(19) United States
(12) Patent Application Publication
(10) Pub. No.: US 2026/0039251 A1
(43) Pub. Date: Feb. 5, 2026

(54) LOW-VOLTAGE SWITCHES IN HIGH VOLTAGE DIGITAL ENVELOPE TRACKING

(71) Applicant: Samsung Electronics Co., Ltd., Suwon-si (KR)

(72) Inventors: Feng Qi, Richardson, TX (US); Xinguang Xu, Allen, TX (US); Shenggang Dong, Dallas, TX (US); Navneet Sharma, Allen, TX (US); Won Suk Choi, McKinney, TX (US); Gang Xu, Allen, TX (US)

(21) Appl. No.: 19/189,151

(22) Filed: Apr. 24, 2025

Related U.S. Application Data
(60) Provisional application No. 63/678,981, filed on Aug. 2, 2024.

(51) Int. Cl. H03F 1/02; H03F 3/24

(52) U.S. Cl. CPC H03F 1/0222; H03F 3/245; H03F 2200/102

(57) ABSTRACT

Methods and systems for applying low-voltage switches in high voltage digital envelope tracking. A method includes setting a generator and a modulator of a digital envelope tracking system to a low voltage and sensing a high input voltage, a low input voltage, a first voltage, and a second voltage using one or more voltage sensors. The method also includes determining if the low input voltage may be connected to the digital envelope tracking system, then generating the second voltage using a first switch, then determining if the high input voltage may be connected to the digital envelope tracking system to generate the first voltage. The method also includes, upon determining that the high input voltage may be connected to the digital envelope tracking system to generate the first voltage, initiating a digital envelope tracking process.

### CROSS-REFERENCE TO RELATED APPLICATIONS AND CLAIM OF PRIORITY

The present application claims priority to U.S. Provisional Patent Application No. 63/678,981, filed on Aug. 2, 2024. The contents of the above-identified patent documents are incorporated herein by reference.

### TECHNICAL FIELD

The present disclosure relates generally to wireless communication systems. More specifically, the present disclosure relates to a system and method for applying low-voltage switches in high voltage digital envelope tracking.

### BACKGROUND

In 6G extreme-MIMO systems, there are likely to be hundreds of power amplifiers in a single base station. These power amplifiers typically consume the majority of the power budget of the base station. Moreover, their power-added efficiency (PAE) is often as low as 20%. The lower PAE is indicative of wasted power that contributes significantly to thermal concerns and increases the operational expenditure costs of a system. Envelope tracking is used to improve power efficiency at different power backoff levels. In a digital envelope tracking (DET) power amplifier, power rails are regulated according to output power and transistor headroom through the DET system. The efficiency of the DET system may require a low “ON” resistance from switches and minimum DC power consumption.

Accordingly, there is a need for systems and methods for improved envelope tracking systems that overcome these challenges.

### SUMMARY

The present disclosure relates generally to wireless communication systems and, more specifically, the present disclosure relates to a system and method for applying low-voltage switches in high voltage digital envelope tracking.

In one embodiment, a method is provided. The method includes setting a generator and a modulator of a digital envelope tracking system to a low voltage and sensing a high input voltage, a low input voltage, a first voltage having a first voltage level, and a second voltage having a second voltage level less than the first voltage level using one or more voltage sensors. The method also includes, during a power up phase, determining if the low input voltage may be connected to the digital envelope tracking system. Upon determining that the low input voltage may be connected to the digital envelope tracking system, the method includes generating the second voltage using the low input voltage and a first switch then determining if the high input voltage may be connected to the digital envelope tracking system to generate the first voltage. The method also includes, upon determining that the high input voltage may be connected to the digital envelope tracking system to generate the first voltage, initiating a digital envelope tracking process.

In another embodiment, an electronic device is provided. The electronic device includes a transceiver, and a processor operably coupled to the transceiver. The processor is configured to set a generator and a modulator of a digital envelope tracking system to a low voltage and sense a high input voltage, a low input voltage, a first voltage having a first voltage level, and a second voltage having a second voltage level less than the first voltage level using one or more voltage sensors. The processor is also configured to cause the electronic device to, during a power up phase, determine if the low input voltage may be connected to the digital envelope tracking system and, upon determining that the low input voltage may be connected to the digital envelope tracking system, generate the second voltage using the low input voltage and a first switch. The processor is further configured to cause the electronic device to determine if the high input voltage may be connected to the digital envelope tracking system to generate the first voltage and, upon determining that the high input voltage may be connected to the digital envelope tracking system to generate the first voltage, initiate a digital envelope tracking process.

In yet another embodiment, a non-transitory computer-readable medium is provided. The non-transitory computer-readable medium includes program code, that when executed by at least one processor of an electronic device, causes the electronic device to set a generator and a modulator of a digital envelope tracking system to a low voltage and sense a high input voltage, a low input voltage, a first voltage having a first voltage level, and a second voltage having a second voltage level less than the first voltage level using one or more voltage sensors. The program code further comprises program code, that when executed by the at least one processor, causes the electronic device to, during a power up phase, determine if the low input voltage may be connected to the digital envelope tracking system and, upon determining that the low input voltage may be connected to the digital envelope tracking system, generate the second voltage using the low input voltage and a first switch. The program code also comprises program code, that when executed by the at least one processor, causes the electronic device to determine if the high input voltage may be connected to the digital envelope tracking system to generate the first voltage and, upon determining that the high input voltage may be connected to the digital envelope tracking system to generate the first voltage, initiate a digital envelope tracking process.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example wireless network according to embodiments of the present disclosure;

FIG. 2 illustrates an example gNB according to embodiments of the present disclosure;

FIG. 3 illustrates an example UE according to embodiments of the present disclosure;

FIG. 4 illustrates an example digital envelope tracking system according to embodiments of the present disclosure;

FIG. 5 illustrates an example flow diagram of a circuit implementation for applying low-voltage switches for high voltage digital envelope tracking according to embodiments of the present disclosure;

FIG. 6 illustrates an example flow chart of a method for applying low-voltage switches for high voltage digital envelope tracking according to embodiments of the present disclosure;

FIG. 7A illustrates an example low-voltage switch circuit to supply a digital envelope tracking system according to embodiments of the present disclosure;

FIG. 7B illustrates an example voltage diagram of the low-voltage switch circuit of FIG. 7A according to embodiments of the present disclosure;

FIG. 8 illustrates an example low-voltage switch circuit to supply a digital envelope tracking system according to embodiments of the present disclosure; and

FIG. 9 illustrates an example low-voltage switch circuit to supply a digital envelope tracking system according to embodiments of the present disclosure.

### DETAILED DESCRIPTION

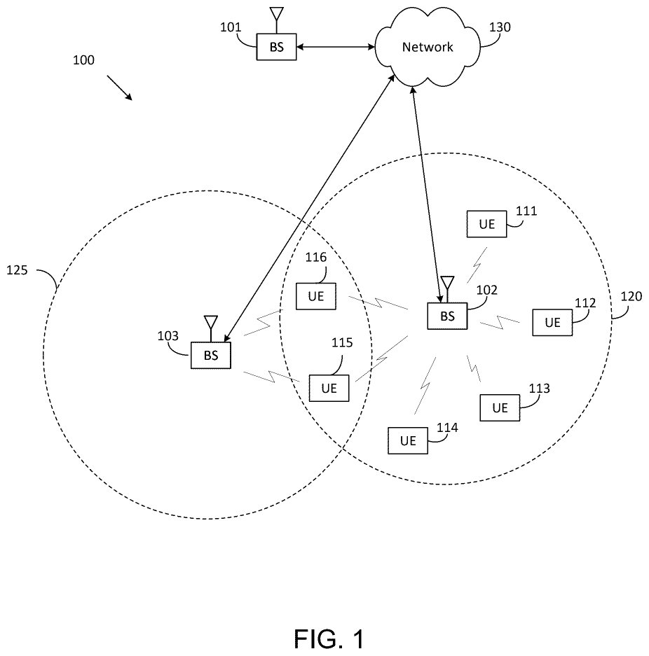

FIG. 1 through FIG. 9, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

As introduced above, power amplifiers typically consume the majority of the power budget of the base station. Moreover, their power-added efficiency (PAE) is often as low as 20%. The lower PAE is indicative of wasted power that contributes significantly to thermal concerns and increases the operational expenditure costs of a system. Additionally, the PAE tends to be lower for higher RF frequencies, further exacerbating the challenge for 6G design where Frequency Range 3 upper mid-band is being considered.

Digital envelope tracking (DET) improves the PAE of a power amplifier by reducing the bias voltage whenever possible. In a digital envelope tracking (DET) power amplifier, power rails are regulated according to output power and transistor headroom through the DET system. The efficiency of the DET system may require a low “ON” resistance from switches and minimum DC power consumption. The switches in DET are selected to sustain the largest signal, which is the voltage between highest supply voltage and ground. Such a selection may also keep the system operating safely. Low-voltage switches are supported by more processes and typically cheaper to fabricate. More importantly, low-voltage switches have better figure of merits compared to the high voltage switches, that may require much less power to drive for the same “ON” resistance. Using low-voltage switches in high voltage DET systems may reduce product cost and improve DET efficiency.

However, to apply low-voltage switches in high voltage DET system, the low-voltage switches need to be kept safe under potentially damaging situations. For example, an over voltage break-down condition may occur at power up and power down transitions. Applying a top side voltage before a bottom side voltage will lead to a transient voltage higher than the normal operation voltage. If the rated voltage of the power switches used is only optimized for normal operation, the power switches may be broken down by the over voltage condition.

Additionally, a reverse shoot-through condition may also occur at power up and power down transitions. Power semiconductor switches, like metal-oxide semiconductor field effect transistors (MOSFETs), insulated-gate bipolar transistors (IGBTs), and high-electron-mobility transistors (HEM Ts), do no block reverse voltage at their “OFF” state. Applying a high reverse voltage to the switch at an “OFF” state will lead to shoot-through, equivalent to applying a high forward voltage to the switch at “ON” state. At power up and power down transitions, unregulated power rails sequences may create a reverse shoot-through condition and damage the power switches.

Accordingly, the present disclosure provides systems and methods for non-uniform discrete envelope tracking. As described herein, the present disclosure includes systems and methods that sense voltages from power rails and lock the DET modulator to bottom side voltage at power up. If the bottom side voltage is higher than the top side voltage, the bottom side voltage source is blocked until the top side voltage is higher than the bottom side voltage within a predefined threshold. The top side voltage source is blocked once the difference between the top side voltage and the bottom side voltage exceeds a range allowed by switches in the DET system. At power down, the DET modulator is locked to the bottom side voltage. If the bottom side voltage is higher than the top side voltage, the bottom side voltage source is blocked until the top side voltage is higher than the bottom side voltage with a predefined threshold. The present disclosure, thus, identifies dangerous conditions and protects the DET system, making the low-voltage switch deployment in high voltage envelope tracking system feasible.

To meet the demand for wireless data traffic having increased since deployment of 4G communication systems and to enable various vertical applications, 5G/NR communication systems have been developed and are currently being deployed. The 5G/NR communication system is considered to be implemented in higher frequency (mmWave) bands, e.g., 28 GHz or 60 GHz bands, so as to accomplish higher data rates or in lower frequency bands, such as 6 GHZ, to enable robust coverage and mobility support. To decrease propagation loss of the radio waves and increase the transmission distance, the beamforming, massive multiple-input multiple-output (MIMO), full dimensional MIMO (FD-MIMO), array antenna, an analog beam forming, large scale antenna techniques are discussed in 5G/NR communication systems.

In addition, in 5G/NR communication systems, development for system network improvement is under way based on advanced small cells, cloud radio access networks (RANs), ultra-dense networks, device-to-device (D2D) communication, wireless backhaul, moving network, cooperative communication, coordinated multi-points (COMP), reception-end interference cancelation and the like.

The discussion of 5G systems and frequency bands associated therewith is for reference as certain embodiments of the present disclosure may be implemented in 5G systems. However, the present disclosure is not limited to 5G systems or the frequency bands associated therewith, and embodiments of the present disclosure may be utilized in connection with any frequency band. For example, aspects of the present disclosure may also be applied to deployment of 5G communication systems, 6G or even later releases which may use terahertz (THz) bands.

FIGS. 1-3 below describe various embodiments implemented in wireless communications systems and with the use of orthogonal frequency division multiplexing (OFDM) or orthogonal frequency division multiple access (OFDMA) communication techniques. The descriptions of FIGS. 1-3 are not meant to imply physical or architectural limitations to the manner in which different embodiments may be implemented. Different embodiments of the present disclosure may be implemented in any suitably arranged communications system.

FIG. 1 illustrates an example wireless network according to embodiments of the present disclosure. The embodiment of the wireless network shown in FIG. 1 is for illustration only. Other embodiments of the wireless network 100 could be used without departing from the scope of this disclosure.

As shown in FIG. 1, the wireless network includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or other data network.

The gNB 102 provides wireless broadband access to the network 130 for a first plurality of user equipments (UEs) within a coverage area 120 of the gNB 102. The first plurality of UEs includes a UE 111, which may be located in a small business; a UE 112, which may be located in an enterprise; a UE 113, which may be a Wifi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, long term evolution (LTE), long term evolution-advanced (LTE-A), WiMAX, WiFi, or other wireless communication techniques.

Depending on the network type, the term “base station” or “BS” can refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3rd generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” can refer to any component such as “mobile station,” “subscriber station,” “remote terminal,” “wireless terminal,” “receive point,” or “user device.” For the sake of convenience, the terms “user equipment” and “UE” are used in this patent document to refer to remote wireless equipment that wirelessly accesses a BS, whether the UE is a mobile device (such as a mobile telephone or smartphone) or is normally considered a stationary device (such as a desktop computer or vending machine).

Dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and manufactured obstructions.

Although FIG. 1 illustrates one example of a wireless network, various changes may be made to FIG. 1. For example, the wireless network could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

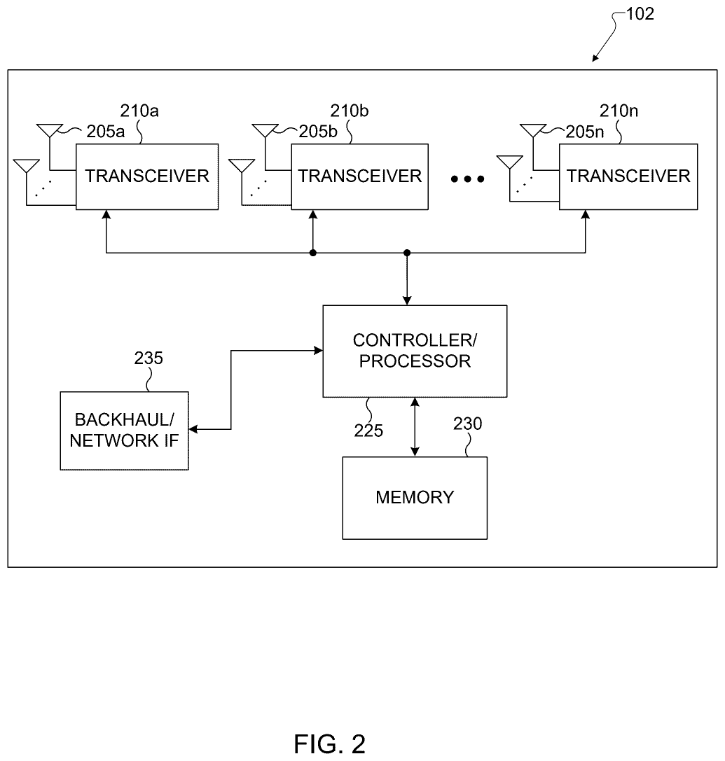

FIG. 2 illustrates an example gNB 102 according to embodiments of the present disclosure. The embodiment of the gNB 102 illustrated in FIG. 2 is for illustration only, and the gNBs 101 and 103 of FIG. 1 could have the same or similar configuration. However, gNBs come in a wide variety of configurations, and FIG. 2 does not limit the scope of this disclosure to any particular implementation of a gNB.

As shown in FIG. 2, the gNB 102 includes multiple antennas 205a-205n, multiple transceivers 210a-210n, a controller/processor 225, a memory 230, and a backhaul or network interface 235.

The transceivers 210a-210n receive, from the antennas 205a-205n, incoming RF signals, such as signals transmitted by UEs in the network 100. The transceivers 210a-210n down-convert the incoming RF signals to generate IF or baseband signals. The IF or baseband signals are processed by receive (RX) processing circuitry in the transceivers 210a-210n and/or controller/processor 225, which generates processed baseband signals by filtering, decoding, and/or digitizing the baseband or IF signals. The controller/processor 225 may further process the baseband signals.

Transmit (TX) processing circuitry in the transceivers 210a-210n and/or controller/processor 225 receives analog or digital data (such as voice data, web data, e-mail, or interactive video game data) from the controller/processor 225. The TX processing circuitry encodes, multiplexes, and/or digitizes the outgoing baseband data to generate processed baseband or IF signals. The transceivers 210a-210n up-converts the baseband or IF signals to RF signals that are transmitted via the antennas 205a-205n.

The controller/processor 225 can include one or more processors or other processing devices that control the overall operation of the gNB 102. For example, the controller/processor 225 could control the reception of UL channel signals and the transmission of DL channel signals by the transceivers 210a-210n in accordance with well-known principles. The controller/processor 225 could support additional functions as well, such as more advanced wireless communication functions. For instance, the controller/processor 225 could support beam forming or directional routing operations in which outgoing/incoming signals from/to multiple antennas 205a-205n are weighted differently to effectively steer the outgoing signals in a desired direction. Any of a wide variety of other functions could be supported in the gNB 102 by the controller/processor 225.

The controller/processor 225 is also capable of executing programs and other processes resident in the memory 230, such as an OS. The controller/processor 225 can move data into or out of the memory 230 as required by an executing process.

The controller/processor 225 is also coupled to the backhaul or network interface 235. The backhaul or network interface 235 allows the gNB 102 to communicate with other devices or systems over a backhaul connection or over a network. The interface 235 could support communications over any suitable wired or wireless connection(s). For example, when the gNB 102 is implemented as part of a cellular communication system (such as one supporting 5G/NR, LTE, or LTE-A), the interface 235 could allow the gNB 102 to communicate with other gNBs over a wired or wireless backhaul connection. When the gNB 102 is implemented as an access point, the interface 235 could allow the gNB 102 to communicate over a wired or wireless local area network or over a wired or wireless connection to a larger network (such as the Internet). The interface 235 includes any suitable structure supporting communications over a wired or wireless connection, such as an Ethernet or transceiver.

The memory 230 is coupled to the controller/processor 225. Part of the memory 230 could include a RAM, and another part of the memory 230 could include a Flash memory or other ROM.

Although FIG. 2 illustrates one example of gNB 102, various changes may be made to FIG. 2. For example, the gNB 102 could include any number of each component shown in FIG. 2. Also, various components in FIG. 2 could be combined, further subdivided, or omitted and additional components could be added according to particular needs.

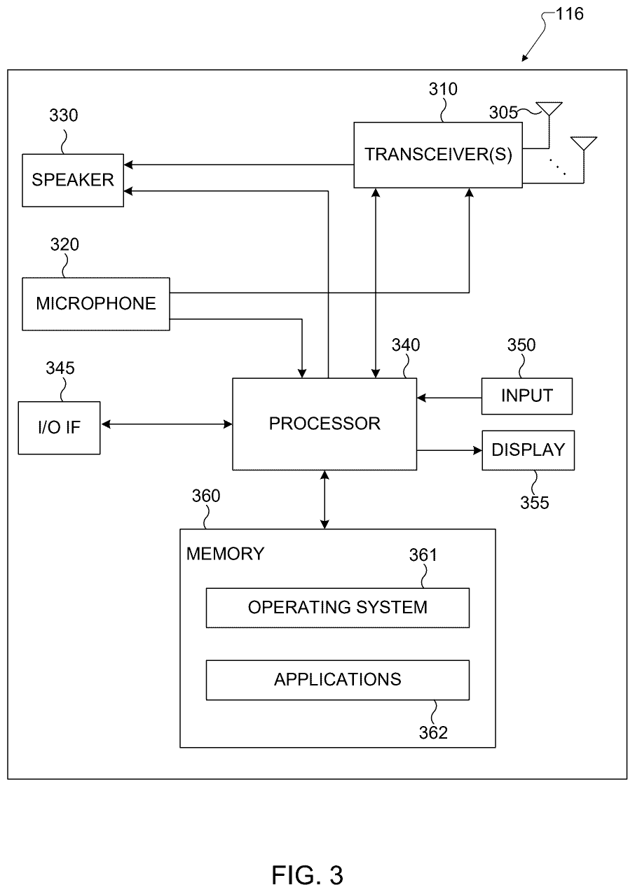

FIG. 3 illustrates an example UE 116 according to embodiments of the present disclosure. The embodiment of the UE 116 illustrated in FIG. 3 is for illustration only, and the UEs 111-115 of FIG. 1 could have the same or similar configuration. However, UEs come in a wide variety of configurations, and FIG. 3 does not limit the scope of this disclosure to any particular implementation of a UE.

As shown in FIG. 3, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives, from the antenna 305, an incoming RF signal transmitted by a gNB of the network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 can include one or more processors or other processing devices and execute the OS 361 stored in the memory 360 in order to control the overall operation of the UE 116. For example, the processor 340 could control the reception of DL channel signals and the transmission of UL channel signals by the transceiver(s) 310 in accordance with well-known principles. In some embodiments, the processor 340 includes at least one microprocessor or microcontroller.

The processor 340 is also capable of executing other processes and programs resident in the memory 360. The processor 340 can move data into or out of the memory 360 as required by an executing process. In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350, which includes for example, a touchscreen, keypad, etc., and the display 355. The operator of the UE 116 can use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3 illustrates one example of UE 116, various changes may be made to FIG. 3. For example, various components in FIG. 3 could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3 illustrates the UE 116 configured as a mobile telephone or smartphone, UEs could be configured to operate as other types of mobile or stationary devices.

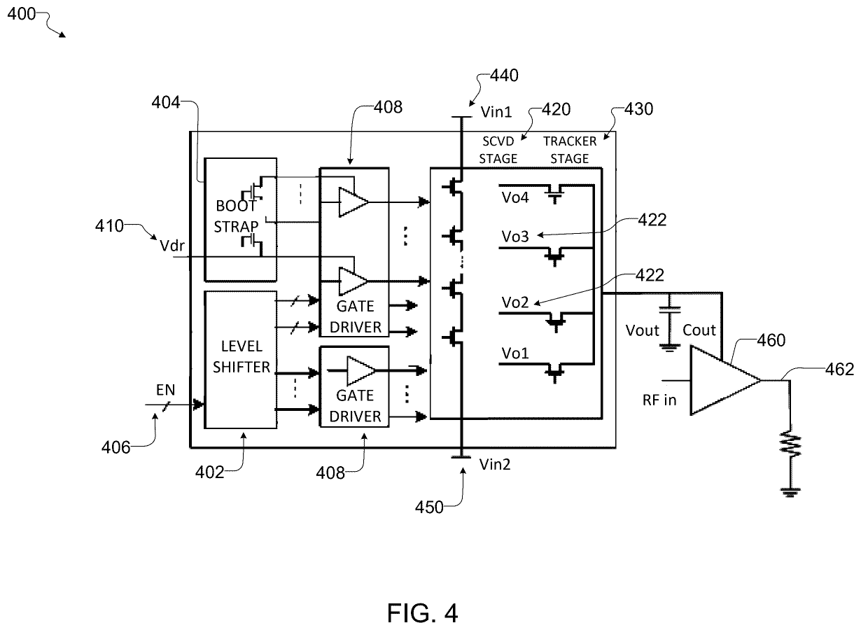

The TX processing circuitry of the gNB 101 may also include one or more power amplifiers coupled to one or more digital-to-analog converters and configured to amplify the baseband signal prior to transmission using the antenna. The one or more power amplifiers receive a supply voltage sufficient to cover the signal envelope of the baseband signal, as shown in FIG. 4.

FIG. 4 illustrates a digital envelope tracking system 400 according to embodiments of the present disclosure. For ease of explanation, the digital envelope tracking system 400 will be described as including one or more components of the wireless network 100 of FIG. 1, such as the gNB 102; however, the digital envelope tracking system 400 could be implemented using any other suitable device or system. The embodiment of the digital envelope tracking system 400 shown in FIG. 4 is for illustration only. Other embodiments of the digital envelope tracking system 400 could be used without departing from the scope of this disclosure.

As shown in FIG. 4, the digital envelope tracking system 400 includes a level shifter 402 and a bootstrap 404. The level shifter 402 is configured to receive an envelope signal 406 (e.g., from a gNB 102) and level shift the envelope signal 406 before passing it to one or more gate drivers 408. The envelope signal 406 and the one or more gate drivers 408 are configured to receive a driver voltage 410. The signals from the one or more gate drivers 408 are provided to a generator 420 and a modulator 430. The generator 420 also receives a first voltage 440 and a second voltage 450. The first voltage 440 is a high voltage and the second voltage 450 is a low voltage, meaning that the first voltage 440 includes a first voltage level and the second voltage includes a second voltage level that is less than the first voltage level of the first voltage 440. The generator 420 uses the first voltage 440 and the second voltage 450 to generate one or more intermediate voltages 422. That is, the generator 420 generates one or more intermediate voltages 422 having voltage levels between the first voltage 440 and the second voltage 450. For example, the generator 420 may generate two intermediate voltages 422 where a first intermediate voltage includes a voltage level of two-thirds of the difference between the first voltage 440 and the second voltage 450 above the second voltage 450 and a second intermediate voltage includes a voltage level of one-third of the difference between the first voltage 440 and the second voltage 450 above the second voltage 450. Alternatively, other intermediate voltage levels may be used, such as non-uniform voltages or more than two intermediate voltages, such as three or more.

The modulator 430 receives the first voltage 440, the second voltage 450, and the one or more intermediate voltages 422 and provides them to a power amplifier 460. The power amplifier 460 then uses the first voltage 440, the second voltage 450, and the one or more intermediate voltages 422 to amplify an RF signal corresponding to the envelope signal 406 to produce an output signal 462.

As shown in FIG. 4, the generator 420 includes six switches and the modulator 430 includes four switches. This configuration allows for four voltage levels (e.g., the first voltage 440, the second voltage 450, and two of the one or more intermediate voltages 422) to be provided to the power amplifier 460. For example, two switches are coupled to the first voltage 440 and configured to generate a first of the one or more intermediate voltages 422, an additional two switches are coupled to the first of the one or more intermediate voltages 422 and configured to generate a second of the one or more intermediate voltages 422, and a third set of two switches are coupled between the second of the one or more intermediate voltages 422 and the second voltage 450. Additionally, the each of the four switches of the modulator 430 are configured to receive one of the first voltage 440, the second voltage 450, the first of the one or more intermediate voltages 422, or the second of the one or more intermediate voltages 422. The modulator 430 then determines which of the voltages (e.g., the first voltage 440, the second voltage 450, the first of the one or more intermediate voltages 422, or the second of the one or more intermediate voltages 422) to provide to the power amplifier 460 based on the envelope signal 406.

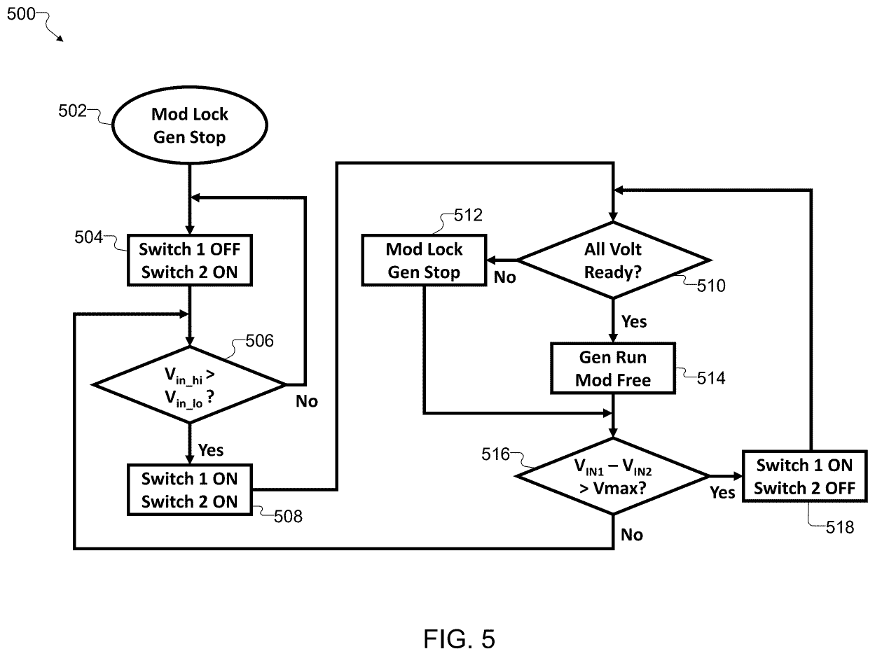

Although FIG. 4 illustrates one example of a digital envelope tracking system, various changes may be made to FIG. 4. For example, the digital envelope tracking system may include switching devices prior to supplying the first voltage 440 and the second voltage 450 to the generator 420 and the modulator 430 to adapt to over voltage breakdown and reverse shoot-through conditions, which offers higher drain-source voltage (V ds) and high reverse bias voltage to prevent damage under such conditions as shown in FIG. 5.

FIG. 5 illustrates an example flow diagram of a circuit implementation 500 for applying low-voltage switches for high voltage digital envelope tracking according to embodiments of the present disclosure. The embodiment of the circuit implementation 500 shown in FIG. 5 is for illustration only. Other embodiments of the circuit implementation 500 could be used without departing from the scope of this disclosure.

As shown in FIG. 5, the circuit implementation 500 begins from an initial state at power up and ends after power down. The initial and final state are the same. The generator is set to a stop state and the modulator is set to lock to the second voltage 450 in operation 502. Additionally, operation 504 sets a first switch of a plurality of low-voltage switches to OFF and a second switch of the plurality of low-voltage switches to ON. At the power up, the circuit implementation 500 circulates among the steps and react to change from voltages in real time. With this way, the plurality of low-voltage switches is kept from dangerous conditions, allowing them to operate in high voltage DET/SPT.

In operation 506, a voltage difference between a high input voltage and a low input voltage is sensed to give feedback to a first comparator determining if the low input voltage can be connected to a DET system. Initially, the first switch stays OFF. The first switch will not be turned ON (operation 508) until the low input voltage is less than the high input voltage. When the input shows the low input voltage is greater than the high input voltage again, the second switch will be turn back to an OFF state.

The voltage difference between the first voltage and the second voltage (operation 516) provides feedback to second comparator determining if the high input voltage may stay connected to the DET system. Initially, the second switch stays ON. The second switch will be turned OFF (operation 518) once the voltage difference between the first voltage and the second voltage exceeds a predetermined threshold (e.g., determined by limitations of the switching devices in the DET system). When the voltage difference between the first voltage and the second voltage falls back within the predetermined threshold with a hysteresis, the second switch will be turn back to ON (operation 508).

The second voltage at output gives feedback to a comparator circuit determining if the DET system can start in operation 510. At operation 512, the generator is set to stop and the modulator is set to lock-to-second voltage. When a proper voltage difference between the first voltage and the second voltage at the DET system are established, the generator is turned to run and the modulator is turned to a free-select mode where the modulator is able to select between voltages provided by the generator (e.g., the first voltage 440, the second voltage 450, or the one or more intermediate voltages 422) in operation 514. When voltage difference between the first voltage and the second voltage reaches the predetermined threshold allowed by switching devices in the DET system (operation 516), the second switch will be turned OFF (operation 518) and the DET system keeps running to drain power stored by capacitor across first voltage and second voltage. When voltage difference between the first voltage and the second voltage drops lower than proper values, high voltage the second switch will be turned back ON.

Although FIG. 5 illustrates one example of a circuit implementation for applying low-voltage switches for high voltage digital envelope tracking, various changes may be made to FIG. 5. For example, while shown as a series of operations, various operations in FIG. 5 could occur any number of times.

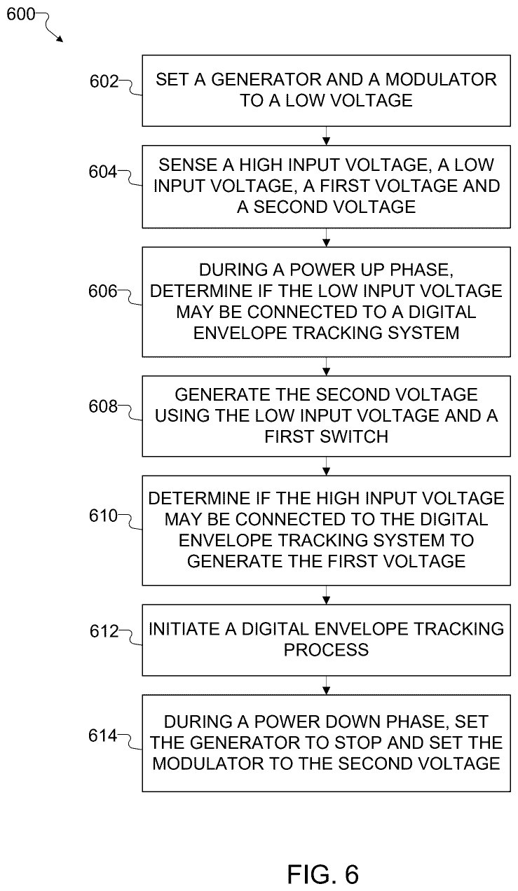

FIG. 6 illustrates an example method 600 for applying low-voltage switches for high voltage digital envelope tracking according to embodiments of the present disclosure. An embodiment of the method illustrated in FIG. 6 is for illustration only. One or more of the components illustrated in FIG. 6 may be implemented in specialized circuitry configured to perform the noted functions or one or more of the components may be implemented by one or more processors executing instructions to perform the noted functions. Other embodiments of non- uniform discrete envelope tracking could be used without departing from the scope of this disclosure.

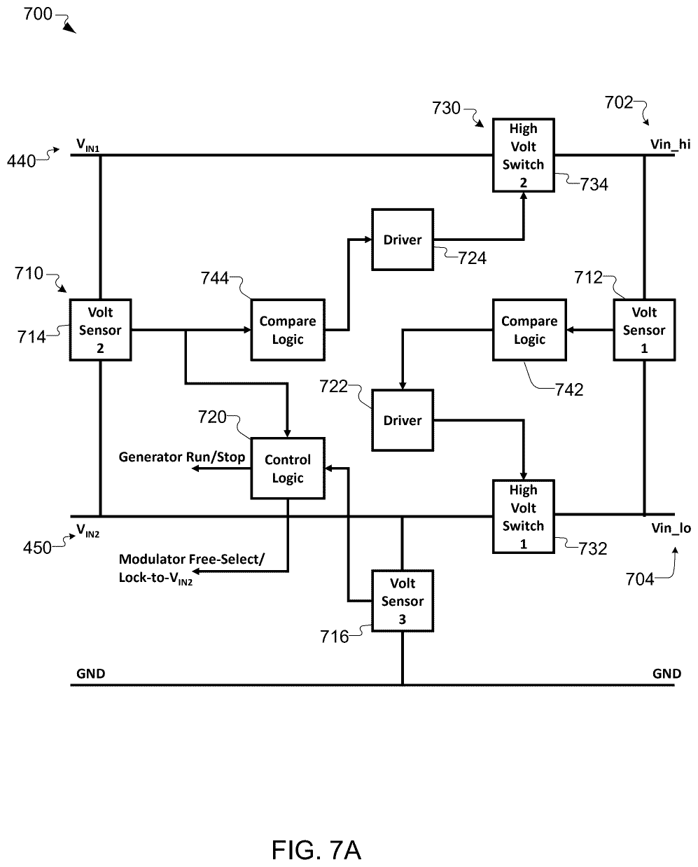

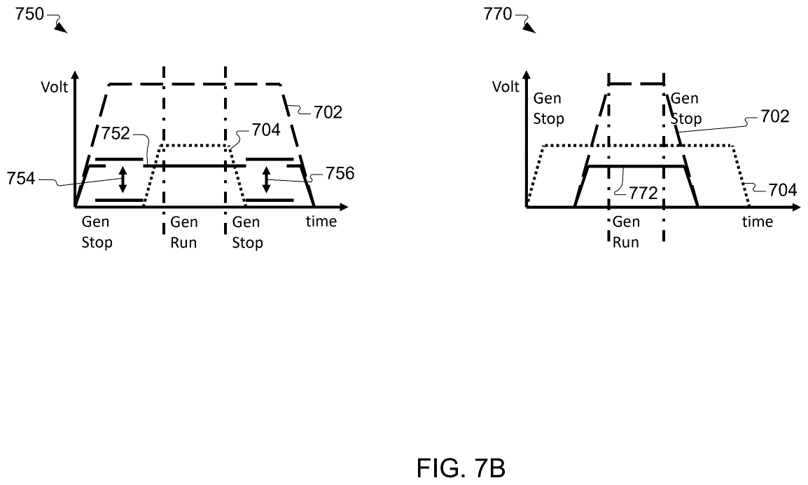

FIG. 7A illustrates an example switch circuit 700 to supply a digital envelope tracking system 400 according to embodiments of the present disclosure. The embodiment of the switch circuit 700 shown in FIG. 7A is for illustration only. Other embodiments of the switch circuit 700 could be used without departing from the scope of this disclosure.

As shown in FIG. 6, a generator 420 and a modulator of a digital envelope tracking system 400 is set at step 602. For example, the generator 420 is set to a stop state using a control circuit 720 of the switch circuit 700. The modulator 430 may be set to a lock-to-second voltage 450 state using the control circuit 720.

A high input voltage 702, a low input voltage 704, a first voltage 440 having a first voltage level, and a second voltage 450 having a second voltage level less than the first voltage level is then sensed using one or more voltage sensors 710 at step 604. For example, as shown in FIG. 7A, the switch circuit 700 includes a high input voltage 702, a low input voltage 704, the first voltage 440, and the second voltage 450. The switch circuit 700 further includes one or more voltage sensors 710, which may include a first voltage sensor 712 coupled between the high input voltage 702 and the low input voltage 704, and a second voltage sensor 714 coupled between the first voltage 440 and the second voltage 450, and a third voltage sensor 716 coupled between a low power rail (e.g., the coupling between the low input voltage 704 and the second voltage 450), and ground. The one or more voltage sensors 710 may be used to sense the high input voltage 702, the low input voltage 704, the first voltage 440, and the second voltage 450.

During a power up phase, the low input voltage 704 may be determined to be connected to the digital envelope tracking system 400 at step 606. For example, the switch circuit 700 may supply the high input voltage 702 to the generator 420 via the first voltage 440. The switch circuit 700 may then determine, using a first comparator circuit 742 coupled to the one or more voltage sensors 710 (e.g., the first voltage sensor 712), whether the high input voltage 702 is greater than the low input voltage 704. U pon determining that the high input voltage 702 is not greater than the low input voltage 704, the switch circuit 700 may block the low input voltage 704 from supplying the generator 420 using one or more switches 730 (e.g., a first switch 732 coupled between the low input voltage 704 and the second voltage 450) and drive circuits (e.g., a first driver 722 coupled to the first switch 732 and a second driver 724 coupled to the second switch 734).

Upon determining that the low input voltage 704 may be connected to the digital envelope tracking system 400, the second voltage 450 may be generated using the low input voltage 704 and a first switch at step 608. For example, the first switch 732 may be switched on an ON state, allowing the low input voltage 704to generate the second voltage 450.

During a power up phase, the high input voltage 702 may be determined to be connected to the digital envelope tracking system 400 to generate the first voltage 440 at step 610. For example, the switch circuit 700 may set a second switch 734 coupled between the high input voltage 702 and the first voltage 440 to an OFF state. The switch circuit 700 may then determine whether a voltage difference between the first voltage 440 and the second voltage 450 exceeds a predetermined threshold using the second voltage sensor 714 coupled between the first voltage 440 and the second voltage 450. Upon determining that the voltage difference between the first voltage 440 and the second voltage 450 does not exceed a predetermined threshold, the switch circuit 700 may set the second switch 734 to an ON state. After setting the second switch 734 to an ON state, the switch circuit 700 may monitor the voltage difference between the first voltage 440 and the second voltage 450 (e.g., using the second voltage sensor 714) to determine if the voltage difference exceeds the predetermined threshold. Upon determining that the voltage difference between the first voltage 440 and the second voltage 450 does not exceed a predetermined threshold, the switch circuit 700 may set the second switch 734 to an OFF state.

Upon determining that the high input voltage 702 may be connected to the digital envelope tracking system 400 to generate the first voltage 440, a digital envelope tracking process may be initiated at step 612. For example, the switch circuit 700 may initiate the generator 420 and allow the modulator 430 to supply the first voltage 440, the second voltage 450, and generated intermediate voltages 422 to the power amplifier 460. The switch circuit 700 may determine whether a voltage difference between the first voltage 440 and the second voltage 450 exceeds a predetermined threshold during operation of the digital envelope tracking process. If so, and upon determining that the voltage difference between the first voltage 440 and the second voltage 450 exceeds a predetermined threshold, the switch circuit 700 may block supply of the high input voltage 702 while running the digital envelope tracking process by switching the second switch to an OFF state.

During a power down phase, the generator 420 is set to stop and set the modulator 430 is set to the second voltage 450 at step 614.

As shown in FIG. 7A, the switch circuit 700 serves the key functions: (i) keep voltage difference between the first voltage 440 and the second voltage 450 within an allowed range for both generator 420 and modulator switches, (ii) block reverse bias voltage on the generator switches, and (iii) indicate the qualification of generator run and stop conditions and modulator free-select and lock-to-between conditions. To fulfill the functions, the voltage difference between the high input voltage 702 and the low input voltage 704 and the voltage difference between the first voltage 440 and the second voltage 450 are sensed at both the input and the output of the switch circuit 700 as well as within the switch circuit 700.

FIG. 7B illustrates example voltage diagrams 750, 770 of the switch circuit according to embodiments of the present disclosure. In particular, the voltage diagrams 750, 770 are generated by the switch circuit as a result of executing the method 600 of FIG. 6. The embodiment of the voltage diagrams 750, 770 shown in FIG. 7 are for illustration only. Other embodiments of the voltage diagrams 750, 770 could be used without departing from the scope of this disclosure.

As shown in FIG. 7B, the voltage diagram 750 includes a supplied voltage 752 between the high input voltage 702 and the low input voltage 704 is supplied to the digital envelope tracking system 400. During a generator stop state, the high input voltage 702 rises and plateaus before the low input voltage 704 rises. If the supplied voltage 752 is within a first predetermined threshold 754, the generator run state begins with both the high input voltage 702 and the low input voltage 704 remaining substantially constant. If either the high input voltage 702 or the low input voltage 704 experience dramatic increases or decreases during operation in the generator run state, the switch circuit 700 will take protective action (e.g., switching either the first switch 732 or the second switch 734 OFF). During the generator stop state of a power down phase, the low input voltage 704 decreases before the high input voltage 702 decreases within a second predetermined threshold 756.

Similarly, in the voltage diagram 770, the supplied voltage 772 remains below the high input voltage 702 during both a generator stop state and a generator run state. This prevents the supplied voltage 772 from being high enough to damage the low-voltage switches of the switch circuit 700.

The waveform of the supplied voltages 752, 772 at a generator stop state could vary in a range between the high input voltage 702 and the low input voltage 704. However, the waveform keeps Vos low and avoids reverse bias so that low-voltage switches stay within proper operating conditions. This allows the safe use of low-voltage switches in high voltage DET systems. By incorporating the low-voltage switches, the DET system will be more cost-effective as the low-voltage switches are supported by more diversified processes and may require less area on a substrate.

Although FIG. 6 illustrates one example method for applying low-voltage switches for high voltage digital envelope tracking, various changes may be made to FIG. 6. For example, while shown as a series of steps, various steps in FIG. 6 could overlap, occur in parallel, occur in a different order, or occur any number of times.

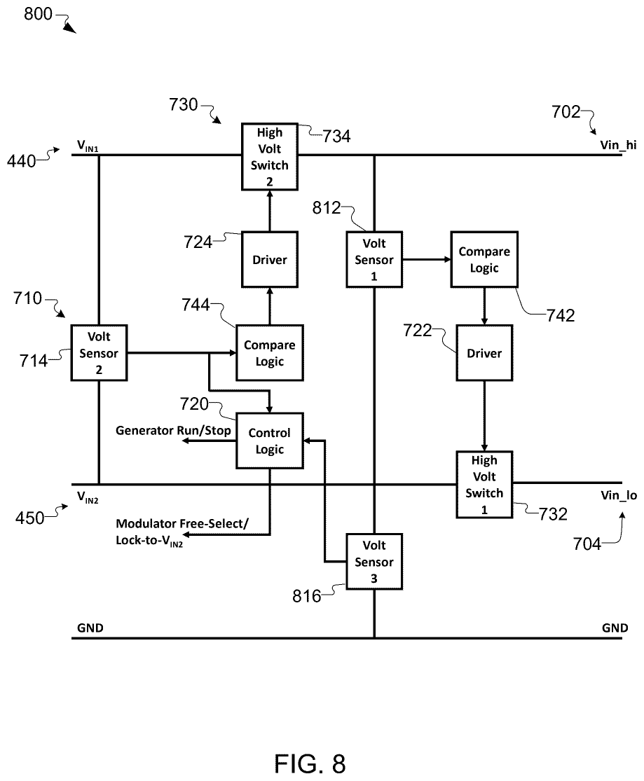

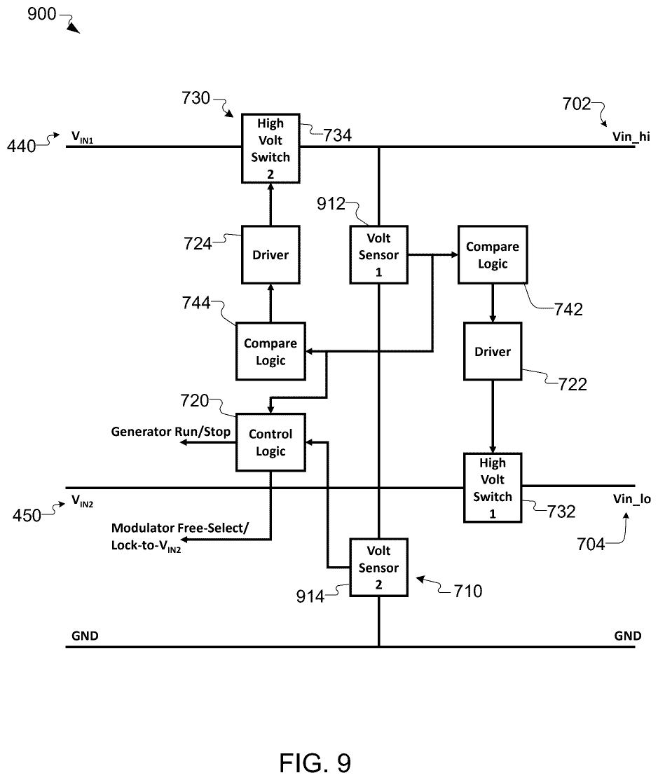

Although FIGS. 7A-7B illustrate examples of a switch circuit and its resulting voltage diagrams, various changes may be made to FIGS. 7A-7B. For example, the switch circuit can be expanded by changing voltage sensing connection in block diagrams as shown in FIGS. 8 and 9.

FIG. 8 illustrates an example switch circuit 800 to supply a digital envelope tracking system according to embodiments of the present disclosure. The embodiment of the switch circuit 800 shown in FIG. 8 is for illustration only. Other embodiments of the switch circuit 800 could be used without departing from the scope of this disclosure. The switch circuit 800 is configured similarly to switch circuit 700 of FIG. 7A, except as otherwise described.

As shown in FIG. 8, the switch circuit 800 includes a first voltage sensor 812 and a third voltage sensor 816 “stacked” such that the first voltage sensor 812 is sensing the voltage difference between the high input voltage 702 and the low input voltage 704 while the third voltage sensor 816 is measuring the voltage difference between the high input voltage 702 and ground directly, compared to the first voltage sensor 712 and the third voltage sensor 716 being separated by the first switch 732 in the switch circuit 700. The first voltage sensor 812 inputs the measured voltage difference to the first comparator circuit 742 and the third voltage sensor 816 inputs the measured voltage difference to the control circuit 720 directly.

Although FIG. 8 illustrates one example of a switch circuit 800 to supply a digital envelope tracking system, various changes may be made to FIG. 8. For example, fewer voltage sensors may be used to implement a switch circuit as shown in FIG. 9.

FIG. 9 illustrates an example switch circuit 900 to supply a digital envelope tracking system according to embodiments of the present disclosure. The embodiment of the switch circuit 900 shown in FIG. 9 is for illustration only. Other embodiments of the switch circuit 900 could be used without departing from the scope of this disclosure. The switch circuit 900 is configured similarly to switch circuit 700 of FIG. 7A, except as otherwise described.

As shown in FIG. 9, a first voltage sensor 912, disposed between the high input voltage 702 and the low input voltage 704, is coupled to the control circuit 720 and the first comparator circuit 742. Additionally, the switch circuit 900 includes only two voltage sensors, the first voltage sensor 912 and a second voltage sensor 914 coupled between the first voltage sensor 912 and ground. As such, the first voltage sensor 912 also provides a measurement of a voltage difference between the first voltage 440 and the second voltage 450 to the second comparator circuit 744.

This allows the first voltage sensor 912 to directly input the measured voltage difference directly to the control circuit 720 and consolidates functionality of the switch circuit 900, allowing the control circuit 720 to control the switch circuit 700 more quickly while reducing space required on a substrate.

Although FIG. 9 illustrates one example of a switch circuit 900 to supply a digital envelope tracking system, various changes may be made to FIG. 9. For example, various components of FIG. 9 could be combined, further subdivided, or omitted and additional components could be added according to particular needs.

The above flowcharts illustrate example methods that can be implemented in accordance with the principles of the present disclosure and various changes could be made to the methods illustrated in the flowcharts herein. For example, while shown as a series of steps, various steps in each figure could overlap, occur in parallel, occur in a different order, or occur multiple times. In another example, steps may be omitted or replaced by other steps.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claims scope. The scope of patented subject matter is defined by the claims.

What is claimed is:

1. A method comprising:
setting a generator and a modulator of a digital envelope tracking system to a low voltage;
sensing a high input voltage, a low input voltage, a first voltage having a first voltage level, and a second voltage having a second voltage level less than the first voltage level using one or more voltage sensors;
during a power up phase, determining if the low input voltage may be connected to the digital envelope tracking system;
upon determining that the low input voltage may be connected to the digital envelope tracking system, generating the second voltage using the low input voltage and a first switch;
determining if the high input voltage may be connected to the digital envelope tracking system to generate the first voltage; and
upon determining that the high input voltage may be connected to the digital envelope tracking system to generate the first voltage, initiating a digital envelope tracking process.

2. The method of claim 1, wherein determining if the low input voltage may be connected to the digital envelope tracking system comprises:
supplying the high input voltage to the generator via first voltage;
determining, using a comparator circuit coupled to the one or more voltage sensors, whether the high input voltage is greater than the low input voltage; and
upon determining that the high input voltage is not greater than the low input voltage, blocking the low input voltage from supplying the generator using one or more switches.

3. The method of claim 1, wherein determining if the high input voltage may be connected to the digital envelope tracking system to generate the first voltage comprises:
setting a second switch coupled to the high input voltage and the first voltage to an OFF state;
determining whether a voltage difference between the first voltage and the second voltage exceeds a predetermined threshold; and
upon determining that the voltage difference between the first voltage and the second voltage does not exceed a predetermined threshold, setting the second switch to an ON state.

4. The method of claim 3, wherein determining if the high input voltage may be connected to the digital envelope tracking system to generate the first voltage further comprises:
after setting the second switch to an ON state, monitoring the voltage difference between the first voltage and the second voltage to determine if the voltage difference exceeds the predetermined threshold; and
upon determining that the voltage difference between the first voltage and the second voltage does not exceed a predetermined threshold, setting the second switch to an OFF state.

5. The method of claim 1, wherein initiating a digital envelope tracking process comprises:
initiating the generator;
allowing the modulator to supply the first voltage, the second voltage, and generated intermediate voltages to a power amplifier; and
determining whether a voltage difference between the first voltage and the second voltage exceeds a predetermined threshold.

6. The method of claim 5, wherein initiating a digital envelope tracking process further comprises:
upon determining that the voltage difference between the first voltage and the second voltage exceeds a predetermined threshold, blocking supply of the high input voltage while running the digital envelope tracking process.

7. The method of claim 1, further comprising:
during a power down phase, setting a generator to stop and setting the modulator to the second voltage.

8. An electronic device, comprising:
a digital envelope tracking system, comprising:
a generator; and
a modulator; and
a processor operably coupled to the digital envelope tracking system, configured to cause the electronic device to:
set the generator and the modulator to a low voltage;
sense a high input voltage, a low input voltage, a first voltage having a first voltage level, and a second voltage having a second voltage level less than the first voltage level using one or more voltage sensors;
during a power up phase, determine if the low input voltage may be connected to the digital envelope tracking system;
upon determining that the low input voltage may be connected to the digital envelope tracking system, generate the second voltage using the low input voltage and a first switch;
determine if the high input voltage may be connected to the digital envelope tracking system to generate the first voltage; and
upon determining that the high input voltage may be connected to the digital envelope tracking system to generate the first voltage, initiate a digital envelope tracking process.

9. The electronic device of claim 8, wherein the processor, when causing the electronic device to determine if the low input voltage may be connected to the digital envelope tracking system, is further configured to cause the electronic device to:
supply the high input voltage to the generator via first voltage;
determine, using a comparator circuit coupled to the one or more voltage sensors, whether the high input voltage is greater than the low input voltage; and
upon determining that the high input voltage is not greater than the low input voltage, block the low input voltage from supplying the generator using one or more switches.

10. The electronic device of claim 8, wherein the processor, when causing the electronic device to determine if the high input voltage may be connected to the digital envelope tracking system to generate the first voltage, is further configured to cause the device to:
set a second switch coupled to the high input voltage and the first voltage to an OFF state;
determine whether a voltage difference between the first voltage and the second voltage exceeds a predetermined threshold; and
upon determining that the voltage difference between the first voltage and the second voltage does not exceed a predetermined threshold, set the second switch to an ON state.

11. The electronic device of claim 10, wherein the processor, when causing the electronic device to determine if the high input voltage may be connected to the digital envelope tracking system to generate the first voltage, is further configured to cause the device to:
after setting the second switch to an ON state, monitor the voltage difference between the first voltage and the second voltage to determine if the voltage difference exceeds the predetermined threshold; and
upon determining that the voltage difference between the first voltage and the second voltage does not exceed a predetermined threshold, set the second switch to an OFF state.

12. The electronic device of claim 8, wherein the processor, when causing the electronic device to initiate a digital envelope tracking process, is further configured to cause the device to:
initiate the generator;
allow the modulator to supply the first voltage, the second voltage, and generated intermediate voltages to a power amplifier; and
determine whether a voltage difference between the first voltage and the second voltage exceeds a predetermined threshold.

13. The electronic device of claim 12, wherein the processor, when causing the electronic device to initiate a digital envelope tracking process, is further configured to cause the device to:
upon determining that the voltage difference between the first voltage and the second voltage exceeds a predetermined threshold, block supply of the high input voltage while running the digital envelope tracking process.

14. The electronic device of claim 8, wherein the processor is further configured to cause the device to:
during a power down phase, set the generator to stop and set the modulator to the second voltage.

15. A non-transitory computer-readable medium comprising program code, that when executed by at least one processor of an electronic device, causes the electronic device to:
set a generator and a modulator of a digital envelope tracking system to a low voltage;
sense a high input voltage, a low input voltage, a first voltage having a first voltage level, and a second voltage having a second voltage level less than the first voltage level using one or more voltage sensors;
during a power up phase, determine if the low input voltage may be connected to the digital envelope tracking system;
upon determining that the low input voltage may be connected to the digital envelope tracking system, generate the second voltage using the low input voltage and a first switch;
determine if the high input voltage may be connected to the digital envelope tracking system to generate the first voltage; and
upon determining that the high input voltage may be connected to the digital envelope tracking system to generate the first voltage, initiate a digital envelope tracking process.

16. The non-transitory computer-readable medium of claim 15, wherein the program code, that when executed by the at least one processor, causes the electronic device to determine if the low input voltage may be connected to the digital envelope tracking system, further comprises program code, that when executed by the at least one processor, causes the electronic device to:
supply the high input voltage to the generator via first voltage;
determine, using a comparator circuit coupled to the one or more voltage sensors, whether the high input voltage is greater than the low input voltage; and
upon determining that the high input voltage is not greater than the low input voltage, block the low input voltage from supplying the generator using one or more switches.

17. The non-transitory computer-readable medium of claim 15, wherein the program code, that when executed by the at least one processor, causes the electronic device to determine if the high input voltage may be connected to the digital envelope tracking system to generate the first voltage, further comprises program code, that when executed by the at least one processor, causes the electronic device to:
set a second switch coupled to the high input voltage and the first voltage to an OFF state;
determine whether a voltage difference between the first voltage and the second voltage exceeds a predetermined threshold; and
upon determining that the voltage difference between the first voltage and the second voltage does not exceed a predetermined threshold, set the second switch to an ON state.

18. The non-transitory computer-readable medium of claim 17, wherein the program code, that when executed by the at least one processor, causes the electronic device to determine if the high input voltage may be connected to the digital envelope tracking system to generate the first voltage, further comprises program code, that when executed by the at least one processor, causes the electronic device to:
after setting the second switch to an ON state, monitor the voltage difference between the first voltage and the second voltage to determine if the voltage difference exceeds the predetermined threshold; and
upon determining that the voltage difference between the first voltage and the second voltage does not exceed a predetermined threshold, set the second switch to an OFF state.

19. The non-transitory computer-readable medium of claim 15, wherein the program code, that when executed by the at least one processor, causes the electronic device to initiate a digital envelope tracking process, further comprises program code, that when executed by the at least one processor, causes the electronic device to:
initiate the generator;
allow the modulator to supply the first voltage, the second voltage, and generated intermediate voltages to a power amplifier; and
determine whether a voltage difference between the first voltage and the second voltage exceeds a predetermined threshold.

20. The non-transitory computer-readable medium of claim 19, wherein the program code, that when executed by the at least one processor, causes the electronic device to initiate a digital envelope tracking process, further comprises program code, that when executed by the at least one processor, causes the electronic device to:
upon determining that the voltage difference between the first voltage and the second voltage exceeds a predetermined threshold, block supply of the high input voltage while running the digital envelope tracking process.
